(19) United States
(12) Patent Application Publication
(10) Pub. No.: US 2008/0274569 A1
(43) Pub. Date: Nov. 6, 2008

(54) Method for forming semiconductor ball grid array package

(75) Inventors: Pei-Haw Tsao, Tai-chung (TW); Pao-Kang Niu, Hsinchu City (TW); Liang-Chen Lin, Hsinchu County (TW); I. T. Liu, Yung-Ho City (TW)

Correspondence Address: DUANE MORRIS LLP (TSMC);IP DEPARTMENT, 30 SOUTH 17TH STREET, PHILADELPHIA, PA, 19103-4196, US

(73) Assignee: Taiwan Semiconductor Manufacturing Company, Ltd.

(21) Appl. No.: 12/217,949

(22) Filed: Jul. 10, 2008

Related U.S. Application Data
(62) Division of application No. 11/468,113, filed on Aug. 29, 2006.

(51) Int. Cl. H01L 21/66

(52) U.S. Cl. 438/16; 257/E21.53

(57) ABSTRACT

A method for forming a semiconductor package provides a ball grid array, BGA, formed on a package substrate. The apices of the solder balls of the BGA are all at the same height, even if the package substrate is non-planar. Different solder ball pad sizes are used and tailored to compensate for non-planarity of the package substrate that may result from thermal warpage. Larger size solder ball pads are formed at relatively-high locations on the package substrate. An equal amount of solder is formed on each of the solder ball pads to produce solder balls having different heights and coplanar apices.

### RELATED APPLICATION

This application is a divisional application of U.S. patent application Ser. No. 11/468,113, filed on Aug. 29, 2006, the contents of which are hereby incorporated by reference as if set forth in their entirety.

### FIELD OF THE INVENTION

The present invention relates, most generally, to semiconductor packages and packaging techniques and more particularly to BGA (Ball Grid Array) packages and methods for forming the same.

### BACKGROUND

Virtually all electronic devices and equipment include multiple semiconductor chips. The semiconductor chips are assembled in semiconductor packages that must be joined to other components within the electronic device or system. Various techniques are used to physically and electrically couple the semiconductor package to other electronic components.

One favored technique used for physically and electrically coupling semiconductor packages to other components is to form a Ball Grid Array, BGA, on a semiconductor package substrate of the semiconductor package. The semiconductor package generally contains a semiconductor chip formed within the package and various heat dissipating components, shields and other structural members. The heat dissipating components are necessary because the technique for forming a semiconductor package typically includes joining the semiconductor chip to the semiconductor package substrate using a thermal cure bonding process. Additional thermal treatments are also used to join the other components that form the semiconductor package. These thermal processes often result in warpage of the semiconductor package. This is due in part to the different CTE's, coefficients of thermal expansion, of the different package materials such as the semiconductor chip, the semiconductor package substrate, underfill material used to fill the gap between the semiconductor chip and the package substrate, and the other components. The warpage of the package produces a non-planarity of the coupling surface of the semiconductor package substrate, i.e., the surface upon which the array of solder balls is formed.

BGA packages are produced by forming an array of solder balls on the coupling surface of the package substrate then bonding the solder balls to a further component. If the surface upon which the solder balls are formed is warped, and if each of the solder balls is the same size, then the apices of the solder balls of the ball grid array will not be coplanar but, rather, will be at different heights. A contour map of a surface connecting the apices of the solder balls includes the same contours and deformity as the package substrate itself. When the degree of package warpage reaches a critical level, the non-planarity of the package substrate and solder balls produces a failure in the delicate assembly process. Therefore, in the conventional art, warpage in the package substrate inevitably leads to assembly yield degradation of the BGA semiconductor package.

FIGS. 1 and 2 show a conventional BGA package according to the PRIOR ART. Semiconductor package 3 includes package substrate 5, semiconductor chip 7, heat spreader 9 and stiffener 10 which may be formed of conventional materials and are exemplary only. The components are joined using adhesives 12 and underfill material 14 and the thermal processes used to join the components result in warpage of package substrate 5. The warpage may be to various degrees and when the warpage exceeds a certain tolerance level, e.g., 8 mils, assembly yield becomes degraded. Solder ball pads 19 are formed on coupling surface 11 and FIG. 2 illustrates that solder ball pads 19 are all of the same dimension. Solder balls 13 are formed on each of the respective solder ball pads 19 and using the same amount of solder material. After conventional reflowing, the solder balls 13 are all of about the same dimension. Since each of the solder balls 13 therefore has substantially the same height, it can be seen that, if bonding surface 11 of package substrate 5 is non-planar, so, too is the surface formed by connecting the apices 15 of solder balls 13, i.e., the respective upper points of the solder balls are at different heights. As such, the degree of non-planarity of package substrate 5 is translated to the surface formed by the apices 15 of solder balls 13. Distance 17 therefore represents both the non-planarity of coupling surface 11 of package substrate 5 and the height difference between the apices 15 of solder balls 13. When apices 15 of solder balls 13 are not at the same level, the assembly yield for the semiconductor packages is diminished. Undesirably, the thermal processes necessarily used to join the components of semiconductor package 3 inevitably lead to the warpage, i.e. non-planarity, of package substrate 5 and coupling surface 11.

It would therefore be desirable to produce a semiconductor package that can be reliably assembled even if the package substrate is warped.

### SUMMARY OF THE INVENTION

To address these and other needs, and in view of its purposes, the present invention provides a semiconductor package comprising a package substrate with a plurality of pads formed on a non-planar surface thereof and a corresponding plurality of solder balls, each solder ball joined to a corresponding one of the pads. The solder balls are ovoid or spherical and the plurality of solder balls includes solder balls having different heights such that the respective apices of the plurality of solder balls are essentially coplanar.

According to another aspect, a method is provided for producing a semiconductor package having a package substrate with a plurality of solder balls thereon wherein apices of the solder balls are essentially coplanar. The method includes providing the semiconductor package with a package substrate having a non-planar coupling surface, measuring topography of the non-planar surface, forming a plurality of solder ball pads on the non-planar surface, the plurality of solder ball pads including pads having different diameters. Solder ball pads formed at higher elevations have greater diameters than solder ball pads formed at lower elevations. The method further includes forming a corresponding plurality of solder balls on the plurality of solder ball pads by dispensing a substantially equal amount of solder on each of the pads whereby the solder balls formed on the pads at higher elevation have a height less than the solder balls formed on the pads at lower elevation.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIG. 1 is a cross-sectional view of a conventional semiconductor package exhibiting warpage according to the PRIOR ART;

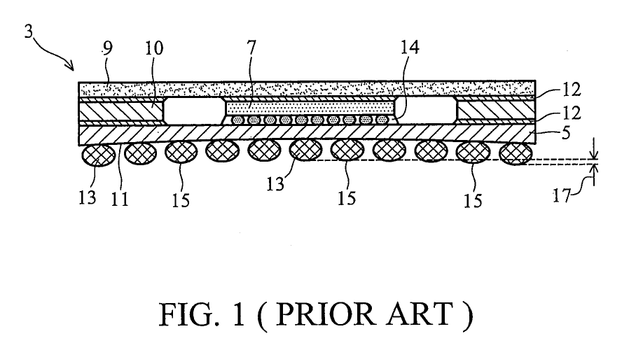

FIG. 2 is a bottom view of a conventional semiconductor package with solder ball pads of the same dimension according to the PRIOR ART;

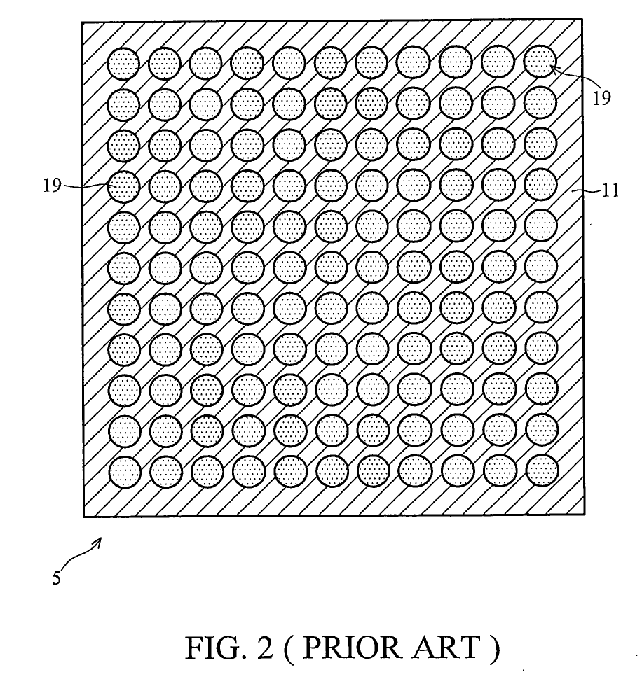

FIG. 3 is a bottom view of an exemplary BGA semiconductor package according to the invention; and

FIG. 4 is a cross-sectional view of an exemplary BGA semiconductor package according to the invention.

### DETAILED DESCRIPTION

The invention provides for measuring surface topology of the bonding or coupling surface of a package substrate in a semiconductor package, in particular measuring the relative elevation of locations on the surface, i.e. the degree of non-planarity, and, responsive to the measurements, forming solder ball pads of different sizes to produce corresponding solder balls of different heights to compensate for the non-planarity of the package substrate and provide an array of solder balls having different heights but such that the tops of all the solder balls are essentially coplanar. The invention is applicable to various ball grid array package types such as PBGA (plastic ball grid array) packages, LFBGA (low profile ball grid array) packages, flip-chip packages, SBGANVBGA (super/viper BGA) packages and may be used for packages of various dimensions and using solder balls of different dimensions and formed of different materials. For example, the invention may be used for CSP (chip scale packages) applications.

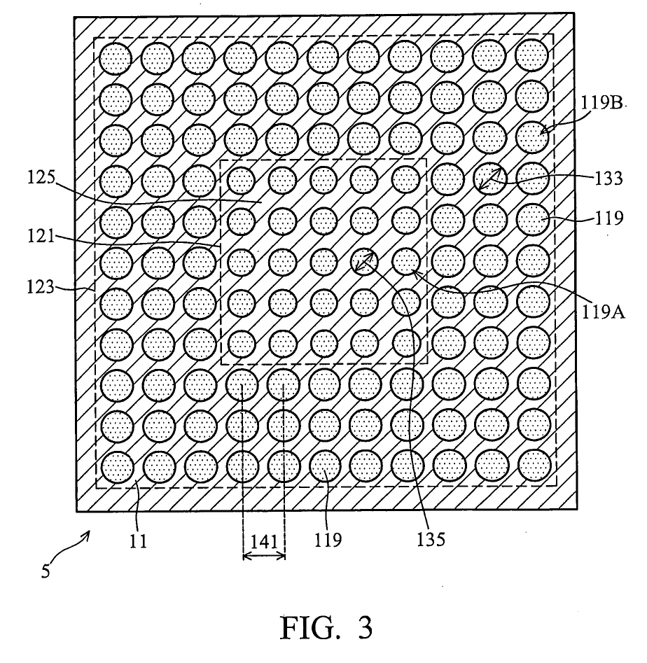

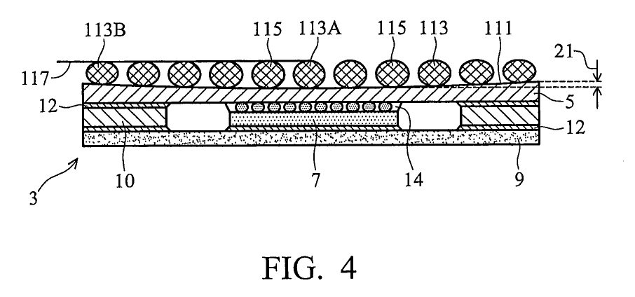

Referring to FIGS. 3 and 4, an exemplary BGA package according to the invention is illustrated. Semiconductor package 3 includes package substrate 5, semiconductor chip 7, heat spreader 9, stiffeners 10, adhesives 12 and underfill material 14. The components are joined using thermal processes that produce a non-planarity in coupling surface 11 of package substrate 5 indicated by distance 21 showing the degree of warpage. An aspect of the invention, however, is that the highest points, i.e. apices 115 of the respective solder balls 113, are coplanar 117 and at the same height and do not include the non-planarity indicated by distance 21 between the highest and lowest points of coupling surface 11, as shown in the cross-sectional view of FIG. 4. The components and relative positions of the components in semiconductor package 3 are intended to be exemplary only. Heat spreader 9 and stiffener 10 are exemplary and in other exemplary embodiments, other components including shields and the like, may be used in conjunction with one or more semiconductor chips 7 that may be formed on package substrate 5.

FIG. 3 shows solder ball pads 119 formed on coupling surface 11 of package substrate 5. According to the method of the invention, after the various components are joined to form semiconductor package 3, but prior to the formation of solder ball pads 19 on bonding surface 11 of package substrate 5, conventional techniques may be used to measure the surface topography of coupling surface 11. Various tools for mapping or otherwise measuring the relative height of coupling surface 11 are available and can be used to determine the elevation at the various locations of coupling surface 11 including distance 21 between high and low points of coupling surface 11. In some exemplary embodiments, the warpage may produce a non-planar surface whereby bonding surface 11 is essentially concave and in other exemplary embodiments, bonding surface 11 may be essentially convex. In still other exemplary embodiments, undulations or ridges may appear throughout coupling surface 11.

According to the method of the invention, solder ball pads 119 are then formed responsive to the surface topology data generated. In particular, at locations of relatively low elevation on coupling surface 11, solder ball pads 119 are formed to have a relatively smaller dimension and at locations of relatively high elevation on coupling surface 11, solder ball pads 119 are formed to have a relatively greater dimension. In the exemplary embodiment illustrated in FIGS. 3 and 4, coupling surface 11 is concave, i.e., the height at the edges of coupling surface 11 is greater than the height at the central portion of coupling surface 11. According to the illustrated exemplary embodiment, two distinct regions of different elevation and different solder ball pad sizes are provided responsive to surface topographical measurements. FIG. 3 illustrates peripheral portion 123 having a relatively higher elevation than central portion 125. Boundary 121 separates peripheral portion 123 and central portion 125. Accordingly, solder ball pads 119A formed within central portion 125 are of smaller dimension than solder ball pads 119B formed in peripheral portion 123. Each of solder ball pads 119A and 119B is essentially circular according to the illustrated exemplary embodiment and solder ball pads 119A formed in central portion 125 include a diameter 135 that is less than diameter 133 of solder ball pads 119B formed in peripheral portion 123 that includes a relative high elevation compared to central portion 125. Diameter 133 may be 10 to 20 percent greater than diameter 135, but other size differences may be used in other exemplary embodiments, depending upon the difference in elevation of the various regions of coupling surface 11 and further depending upon the amount of solder material used. Each of solder ball pads 119A include the same dimensions in the illustrated embodiment as do each of solder ball pads 119B but the two distinct portions, each with identically sized solder balls, is exemplary only. In other exemplary embodiments, more than two different regions, i.e., central portion 125 and peripheral portion 123, may be used. There may be a peripheral portion, a central portion and an intermediate portion therebetween. In yet other exemplary embodiments, the solder ball pad sizes may vary gradually or irregularly throughout coupling surface responsive to the contours mapped by the topography tool.

The dimensions of semiconductor package 3 and coupling surface 11 may vary in exemplary embodiments. Similarly, the sizes of solder ball pads 119 and pitch 141 may also vary in exemplary embodiments. Pitch 141 may vary from about 0.4 mm to about 1.27 mm in one exemplary embodiment, but other suitable pitches may be use din other exemplary embodiments. According to one exemplary embodiment in which pitch 141 is about 1 mm, at least one of the diameters 133, 135 may be about 0.5+/−0.05 mm, but this is exemplary only and various other pitches and diameters may be used in other exemplary embodiments. Diameters 133, 135 may each lie within the range of 0.2 to 0.8 mm in one exemplary embodiment.

An equal amount of solder material is then deposited on each of solder ball pads 119 using conventional methods. Conventional solder materials such as SnAg, other lead-free or lead-containing solder materials may be used. After the solder material is deposited, conventional reflowing processes are used to form solder balls 113 shown in FIG. 4. Applicants have discovered that, when the same amount of solder material is used on solder ball pads having different dimensions, the formed solder balls have different heights after reflow. The solder balls formed on solder ball pads having greater dimensions are formed to include a lower height than solder balls formed using the same amount of solder material on solder ball pads having smaller dimensions. Applicants attribute this difference to surface tension phenomenon, as the solder material does not laterally encroach the initial peripheral boundaries of solder ball pads 119. Solder balls 113 will be spherical or ovoid in shape depending on the amount of solder used and the size of solder ball pad 119 upon which the solder ball is formed. The heights of solder balls 113 may vary and depend upon the amount of solder material used and dimensions of solder ball pads 119. An advantage of the invention is that the apices 115 of solder balls 113A and 113B form plane 117. Coupling surface 11, now with the BGA of solder balls 113 formed thereon, can then be electrically and physically coupled to further electronic components using various conventional techniques.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for providing a semiconductor package having a package substrate with a plurality of solder balls with essentially coplanar apices thereon, said method comprising:
providing said semiconductor package with a package substrate having a non-planar coupling surface;
measuring topography of said non-planar coupling surface;
forming a plurality of solder ball pads on said non-planar surface, said plurality of solder ball pads including solder ball pads having different diameters, said solder ball pads including high pads being at a higher elevation and having a greater diameter than low pads being at a lower elevation; and
forming a corresponding plurality of solder balls on said plurality of solder ball pads by dispensing a substantially equal amount of solder on each of said pads whereby first solder balls formed on said high pads at higher elevation have a height less than second solder balls formed by depositing solder on said low pads.

2. The method as in claim 1, wherein said forming a corresponding plurality of solder balls further comprises reflowing after said depositing.

3. The method as in claim 2, wherein said reflowing produces said solder balls being spherical or ovoid in shape.

4. The method as in claim 2, wherein said forming a corresponding plurality of solder balls and said reflowing produce said plurality of solder balls having essentially coplanar apices.

5. The method as in claim 1, wherein said forming a plurality of solder ball pads further comprises forming intermediate pads having a greater diameter than said low pads and a lesser diameter than said high pads.

6. The method as in claim 5, wherein said forming a corresponding plurality of solder balls further comprises forming intermediate solder balls on said intermediate pads, said intermediate solder balls having an intermediate height less than that of said second solder balls and greater than that of said first solder balls.

7. The method as in claim 1, wherein said forming a corresponding plurality of solder balls produces said plurality of solder balls having essentially coplanar apices.

8. The method as in claim 1, wherein each of said solder ball pads is circular.

9. The method as in claim 8, wherein each of said plurality of circular solder ball pads has an original circumference and each corresponding solder ball includes a circumference that coincides with said original circumference, at said non-planar coupling surface.

10. The method as in claim 1, wherein each of said plurality of solder ball pads has an original peripheral edge and each corresponding solder ball includes a peripheral edge that coincides with said original peripheral edge, at said non-planar coupling surface.

11. The method as in claim 1, wherein each of said solder balls is each joined to and contacts only a corresponding one of said solder ball pads.

12. The method as in claim 1, wherein each of said solder ball is ovoid or spherical.

13. The method as in claim 1, wherein said high pads have a second diameter that is about 10 to 20 percent greater than a first diameter of said low pads.

14. The method as in claim 1, wherein said plurality of pads are formed in an array of orthogonal rows and columns and wherein said second solder balls are centrally disposed and said first solder balls are peripherally disposed.

15. The method as in claim 1, wherein said plurality of pads are formed in an array of orthogonal rows and columns and wherein said second solder balls are peripherally disposed and said first solder balls are centrally disposed.
